(19) United States
(12) Patent Application Publication
(10) Pub. No.: US 2025/0132282 A1
(43) Pub. Date: Apr. 24, 2025

(54) CONTACT DEVICE AND POWER MODULE ARRANGEMENT

(71) Applicant: Robert Bosch GmbH, Stuttgart (DE)

(72) Inventors: Alexander Kaiser, Schoerzingen (DE); Stephan Eisenlauer, Oberriexingen (DE)

(21) Appl. No.: 18/915,518

(22) Filed: Oct. 15, 2024

(30) Foreign Application Priority Data
Oct. 20, 2023 (DE) 10 2023 210 387.7

(51) Int. Cl. H01L 23/00; H01L 23/538; H01L 25/07

(52) U.S. Cl. CPC H01L 24/40; H01L 23/538; H01L 24/37; H01L 25/072; H01L 2224/3701; H01L 2224/40227; H01L 2224/404

(57) ABSTRACT

A contact device for electrically contacting at least two electrical functional components within a connection interface. The contact device includes at least one busbar which extends from a first to a second contact region. When the functional component is electrically contacted by different contact regions of the busbar, a current path can be formed within the busbar between the first and the second contact region. Each contact region has at least one contact connection lug for integral connection to an external contact surface. The electrical contacting of at least one contact connection lug with an external contact surface of one of the functional components is formed via an integral bond. The integral bond is interrupted by at least one through-opening in the contact connection lug such that at least two contact elements which exclusively have portions of the formed integral bond are formed on the contact connection lug.

### FIELD

The present invention relates to a contact device and to a power module arrangement having at least one power module and having at least one contact device which is electrically contacted in a connection interface with the power module, in particular for providing a phase current for an electric machine.

### BACKGROUND INFORMATION

Power module arrangements for motor vehicles, for example, are described in the related art, in which power module arrangements a first connection interface between the at least one power module and a capacitor assembly, which comprises at least one capacitor, or a second connection interface between the at least one power module and a phase connection to an electric machine are produced via welded connections.

It can generally be assumed that the service life of an electric drive of the motor vehicle is at least 15 years or more. Over this period, the welded connection must withstand moisture, temperature changes, mechanical stress, contact with salt and much more without losing its electrical conductivity.

In particular, mechanical stress acts as a negative amplifier for other influencing factors, so that there is a risk of line breakage. These risks are even higher if the line connection is exposed to particular vibrations and/or if disadvantageous stress-related torsion occurs, for example owing to a specific installation position in the motor vehicle.

### SUMMARY

An object of the present invention is that of providing cost-effective electrical contacting, which is technically simple to implement, of at least two electrical functional components of an electrical and/or electronic circuit and/or subcircuit within at least one connection interface, in which stress-induced negative influencing factors on the connection interface that affect the service life are reduced.

This object may be achieved by a contact device and a power module arrangement having at least one power module and having at least one contact device which is electrically contacted in a connection interface by the power module, in particular for providing a phase current for an electric machine, comprising certain features of the present invention.

The present invention relates to a contact device for electrically contacting at least two electrical functional components of an electrical and/or electronic circuit and/or subcircuit within at least one connection interface. The two functional components to be electrically contacted are, for example, a power module and a capacitor as part of a commutation circuit for controlling an electric motor. According to an example embodiment of the present invention, the contact device comprises at least one busbar which extends from at least a first to a second contact connection lug. The contact connection lug therefore comprises a connection surface for electrical contacting. The at least one busbar is designed such that, when the functional component is electrically contacted by different contact connection lugs of the busbar, a current path can be formed within the busbar between the first and the second contact connection lug. The busbar bridges a local spacing between the two functional components to be contacted. The busbar is preferably straight so that the two contact connection surfaces are opposite one another along a straight line. The course of the busbar between the contact connection lugs can also deviate from a straight design and, for example, have a kind of L-shaped or S-shaped directional course. Other courses are however also conceivable. The contact connection lugs are then offset from one another in comparison with the straight design of the busbar. In this case, a contact connection lug generally transitions in a straight line into the further course of the busbar before the course deviates from the straight design. In each case, one contact connection lug is associated with one functional component for electrically contacting an external contact surface. The electrical contacting of at least one contact connection lug with at least one external contact surface of one of the functional components is formed by means of an integral bond, in particular by means of a welded connection. The integral bond is formed between outer boundary edges of the at least one contact connection lug transversely to the extension of the contact connection lug in the direction of the continuation of the busbar, in particular at an angle of 45°-90°, preferably at a right angle. Furthermore, the integral bond is interrupted by at least one through-opening in the contact connection lug such that at least two contact elements which exclusively have portions of the formed integral bond are formed on the contact connection lug. Advantageously, portions of the integral bond are formed by the one or more through-openings, which result overall in a shorter connecting contact length of the integral bond than would otherwise be the case with an integral bond formed continuously across the contact connection lug. In this simple way, the integral bond is mechanically decoupled within the contact region. As a result, the effect of mechanical and/or thermomechanical stresses on such described connections is greatly reduced. In particular, mechanical decoupling leads to flexibility within the contact region, which can reduce stresses that would otherwise arise. Overall, operational reliability over a defined service life can be ensured in the simplest way for such a described contact arrangement. In contrast to different contact connection lugs of the at least one busbar, contact elements K of a contact connection lug are electrically contacted by an identical, contiguous, exposed external contact surface.

Advantageous developments and improvements of the contact device according to the present invention are made possible by the measures disclosed herein.

In an advantageous embodiment of the contact device of the present invention, the through-opening is in the form of an elongate hole, wherein a longitudinal axis of the elongate hole is oriented in the direction of the continuation of the busbar and/or in the direction of an axis of symmetry of the electrically contacted external contact surface of the functional component. An elongate hole means that the flexibility in the contact region is much more pronounced than with just a round hole, for example. Furthermore, a notch effect is reduced by a lateral projection of the integral bond cross section from a longitudinal portion of the elongate hole.

In principle, the through-opening can be made by a material-removing process, for example by sawing, milling, drilling and the like or by means of a punching process, for example. Preferably, the through-opening has rounded edges, as a result of which notch effects are additionally reduced when stresses are active.

Particular advantages are shown in an embodiment of the contact arrangement in which the portions of the integral bond on all the contact elements are arranged along a common axis. In the case of a weld seam connection as the integral bond, imaginary extensions of the portions therefore extend congruently into one another. In this way, it is ensured that material expansion in the contact region caused by temperature influences does not lead to asymmetrical distortion, which could possibly cause unnecessary thermomechanical stresses.

An embodiment of the contact device of the present invention is preferred, in which the portion of the integral bond formed in each case on the contact element extends substantially from an outer boundary edge of the contact connection lug to an outer boundary edge of the through-opening or extends from each outer boundary edge of two through-openings between which a contact element is formed. The boundary edges are generally oriented substantially in the direction of the continuation of the busbar after the contact connection lug. This advantageously means that the entire remaining cross section of the connection surface in the region of the through-opening is used for the integrally bonded electrical contacting. This means that the possible current-carrying capacity of the busbar can be used to its maximum. In consideration of sufficient flexibility versus the maximum required current-carrying capacity of the busbar in the contact region, it is conceivable to provide a size of the through-opening such that a cross section of the connection surface of the contact connection lug that can be used for the integral bond remains at 50-80%, preferably 50-75%, in particular 50-65%. In principle, however, it should be ensured overall that a remaining cross section of the connection surface that has a current-carrying capacity required for the application remains in the contact region.

Advantageous embodiments of the contact arrangement of the present invention can differ from one another depending on the application and the side of a contact connection lug from which mechanical and/or thermomechanical stresses mainly develop. If the stresses are introduced by the functional component which is electrically contacted by a contact connection lug, an embodiment of the contact arrangement is particularly suitable in which at least one, in particular all, of the through-openings of the at least one contact connection lug extends/extend to its end edge, which also forms one of the end edges of the busbar, and the at least one, in particular all, of the through-openings on the side facing away from the end edge, in the direction of the continuation of the busbar, protrudes/protrude beyond the adjacent portions of the integral bond by a distance of from 1 to 30 mm, in particular from 1 to 20 mm. In this respect, the through-opening is open toward the end edge.

If, on the other hand, the mechanical stresses are introduced by the functional component which is electrically contacted integrally by the opposite contact connection lug, an embodiment of the contact arrangement is preferably provided in which at least one, in particular all, of the through-openings of the at least one contact connection lug extends/extend to a distance of from 1 to 30 mm, in particular from 1 to 30 mm, from the end edge, which also forms one of the end edges of the busbar, and the at least one, in particular all, of the through-openings on the side facing away from the end edge, in the direction of the extension of the busbar, extends to a distance from 1 to 30 mm, in particular from 1 to 20 mm, in front of the other contact connection lug. In comparison with the above-described embodiment, the through-opening is therefore closed at the edge, but extends further in the direction of the opposite contact connection lug.

A particularly favorable example embodiment of the contact device of the present invention is provided in that the contact device comprises at least two busbars which are electrically isolated from one another and to which different electrical potentials of the associated functional component can be applied. The electrical isolation can be achieved by maintaining a minimum distance between the two busbars by means of the air gap between them. In order to prevent the two busbars from accidentally touching one another, an electrically insulating material can also be arranged between the two busbars, for example an insulating protective film or an insulating spacer element or the like. For example, two or more busbars of the contact device are embedded in a common electrically insulating enclosure, with at least the contact connection lugs protruding from the enclosure. The enclosure advantageously forms a touch protection means for the contact device, so that there is no immediate danger to people or the environment when the contact device is in operational use, even with high electrical currents and/or voltages and when used properly. The enclosure compound can be provided, for example, by a casting compound, for example made of a ceramic, or by an in particular polymer injection molding compound, for example a molding compound. The electrical insulation can also be used advantageously to connect both busbars so as to hold them in the form of a mounting assembly, so that a connection pattern intended for the application is created by a spatially correct positional arrangement of the contact connection lugs for the electrical contacting of the mounting assembly with the functional components.

It is generally advantageous if the at least one busbar or all busbars of the contact device is/are formed from a plate-like base material having a plate thickness d between two opposite outer surfaces. Thus, the at least one busbar or all busbars of the contact device is or are preferably made of a sheet metal material as the plate material, more preferably of copper or a copper alloy. In this way, such busbars can advantageously be designed as punched and bent parts, which makes cost-effective mass production possible.

The present invention also leads to a power module arrangement having at least one power module which comprises a plurality of semiconductor switches and at least one external contact surface, and having at least one connection interface which comprises at least one contact device in one of the above-described embodiments, wherein at least one contact connection lug of the at least one busbar is integrally connected, in particular by means of a weld seam, to the external contact surface of the power module.

In a further advantageous example embodiment of the power module arrangement of the present invention, a first connection interface comprises a first above-described contact device and is designed to electrically connect at least a first or a second external contact surface of the at least one power module to a first supply connection and to electrically connect at least a third external contact surface of the at least one power module to a second supply connection. Through the first connection interface, the corresponding power module can be electrically connected in one operation to the supply connections, which are provided, for example, by a capacitor assembly. Preferably, a plurality of enclosed busbars of the first contact devices can be arranged at a certain distance from one another in an electrically isolating manner. A second connection interface can comprise a further external contact device and be designed to electrically connect at least one fourth external contact surface of the at least one power module to a load connection. By means of the second connection interface, the corresponding power module can be electrically connected to a phase connection of an electric machine, for example.

In a further advantageous example embodiment of the present invention, the power module arrangement can comprise three power modules. In this case, the at least one fourth external contact surface of a first power module can be electrically connected to a load connection designed as a first phase connection and provide a first phase current for an electric machine. The at least one fourth external contact surface of a second power module can be electrically connected to a load connection designed as a second phase connection and provide a second phase current for the electric machine. The at least one fourth external contact surface of a third power module can be electrically connected to a load connection designed as a third phase connection and provide a third phase current for the electric machine. In addition, the three power modules can each have a first connection interface, which electrically connects the corresponding power module to the first supply connection and the second supply connection, and a second connection interface, which electrically connects the corresponding power module to the corresponding load connection. The power module arrangement with the three power modules can preferably be used as a power output stage for a three-phase electric motor.

Exemplary embodiments of the present invention are shown in the figures and explained in more detail in the following description. In the figures, identical reference signs denote components or elements which perform the same or analogous functions.

### BRIEF DESCRIPTION OF THE DRAWINGS

Further advantages, features and details of the present invention can be found in the following description of preferred exemplary embodiments of the present invention and with reference to the figures.

FIG. 1 is a schematic plan view of an exemplary embodiment of a power module arrangement according to the present invention.

FIG. 2 is a schematic plan view of an exemplary embodiment of a power module for the power module arrangement from FIG. 1, according to the present invention.

FIG. 3 is a schematic sectional view of the power module arrangement from FIG. 1.

FIG. 4A schematically shows an exemplary embodiment of a contact device within the power module arrangement from FIG. 1 in a perspective view, according to the present invention.

FIG. 4B shows the two busbars within the contact device from FIG. 4A in a plan view.

FIG. 4C shows the arrangement of a current sensor device in the region of the through-opening of a contact connection lug.

### DETAILED DESCRIPTION OF EXAMPLE EMBODIMENTS

In the figures, functionally identical components are each denoted by the same reference signs.

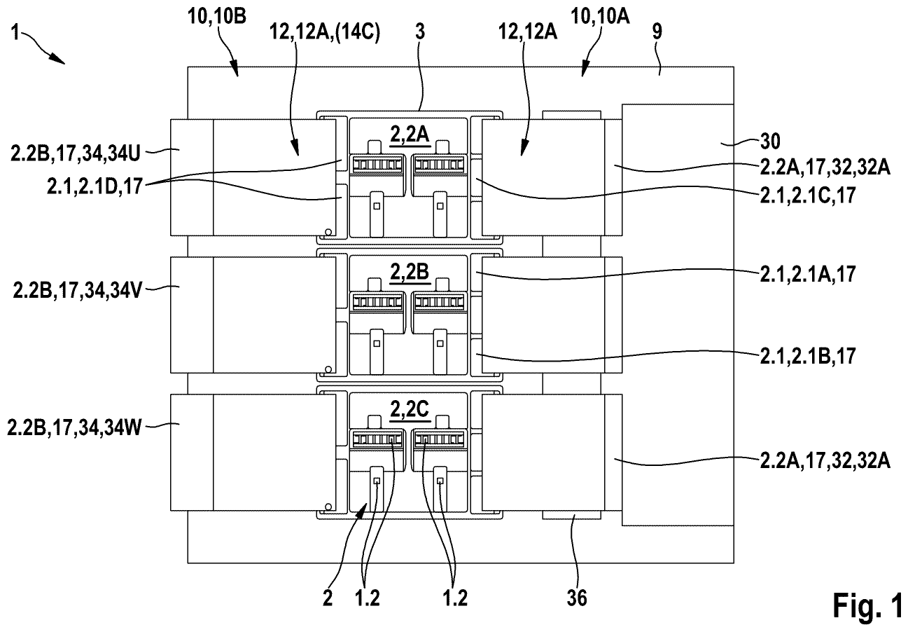

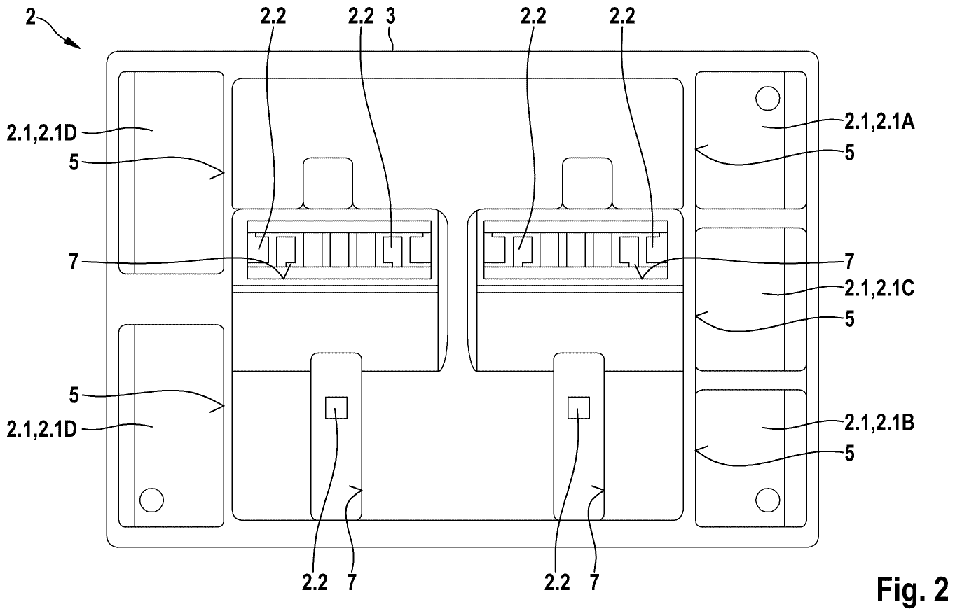

As can be seen from FIGS. 1 to 4C, the shown exemplary embodiment of a power module arrangement 1 according to the present invention comprises at least one power module 2, 2A, 2B, 2C, which comprises a plurality of semiconductor switches (not shown in detail) and at least one external contact surface 2.1, 2.1A, 2.1B, 2.1C, 2.1D, and at least one connection interface 10, 10A, 10B, which comprises at least one contact device 12, 12A, 12B.

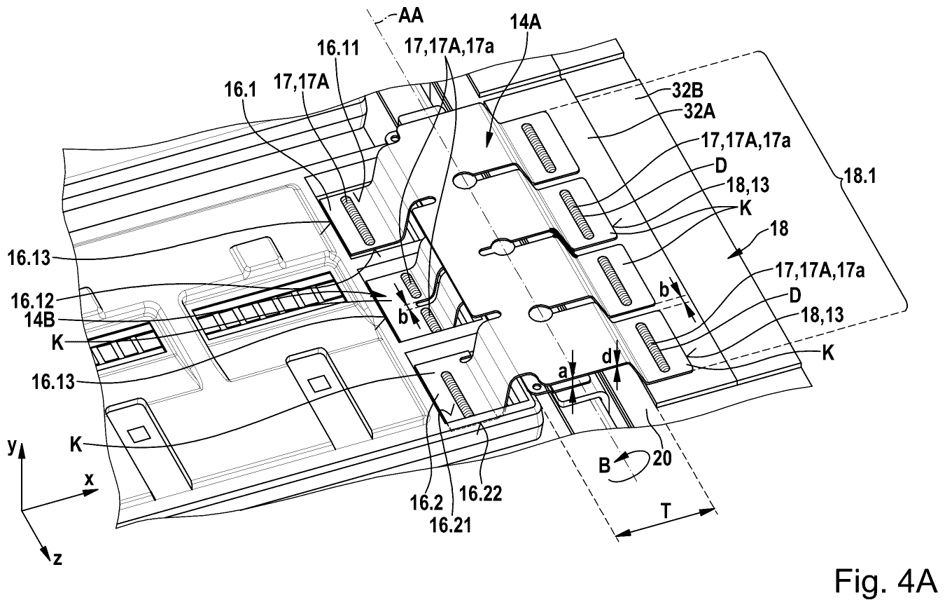

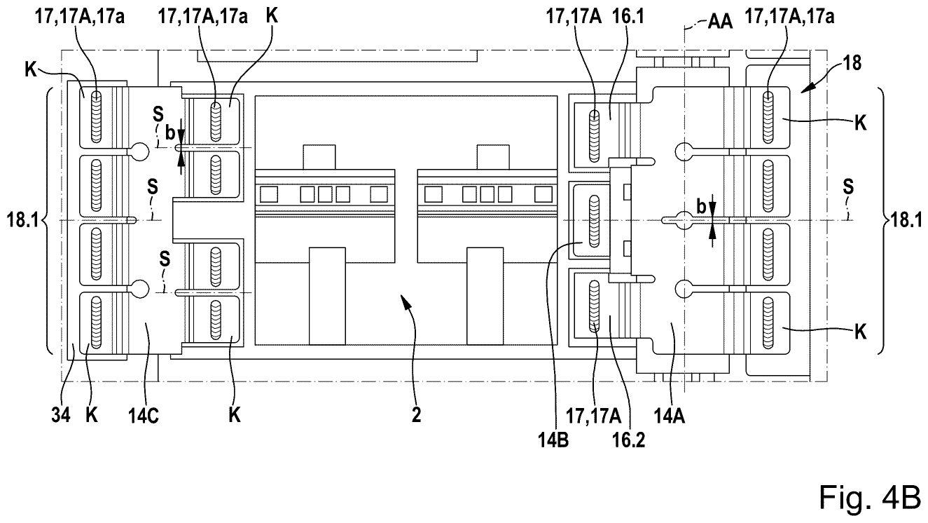

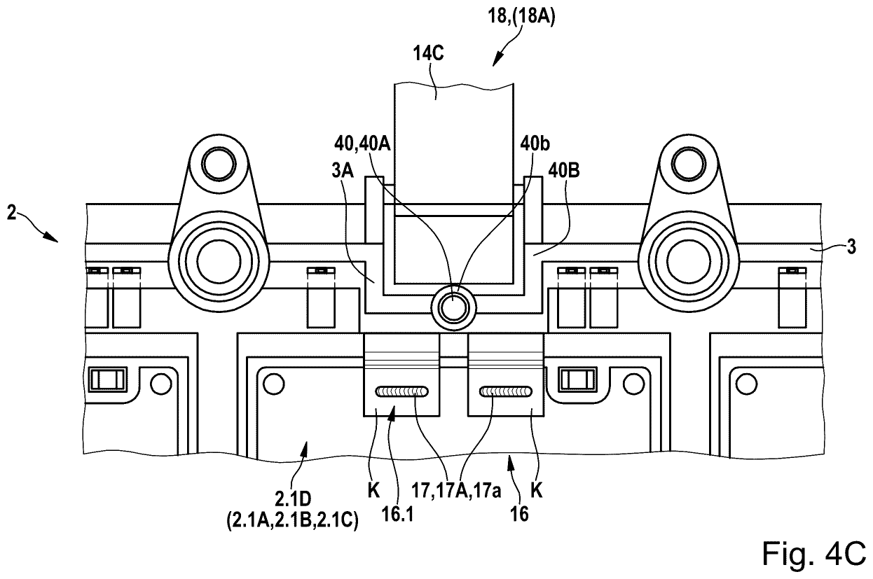

The at least one connection interface 10, 10A, 10B electrically connects the at least one external contact surface 2.1, 2.1A, 2.1B, 2.1C, 2.1D of the power module 2 to at least one first further external contact surface 2.2, 2.2A, for example a first or a second supply connection 32, 32A, 32B, or to at least one second further external contact surface 2.2, 2.2B, for example a load connection 34. The at least one external contact device 12, 12A, 12B is visualized in FIG. 1 merely as a simplified rectangular element. A possible exemplary embodiment can be seen in detail in FIG. 4A to 4C. The at least one external contact device 12, 12A, 12B comprises at least one, two or more busbars 14, 14A, 14B, each having at least one first contact region 16, which electrically contacts the at least one external contact surface 2.1, 2.1A, 2.1B, 2.1C, 2.1D of the power module 2, 2A, 2B, 2C with at least one contact connection lug 16.1, 16.2, and having at least one second contact region 18, which contacts the at least one further external supply connection 32 or the at least one further external load connection 34 with at least one contact connection lug 18.1. The at least one contact connection lug 16.1, 16.2 of the at least one first contact region 16 and the at least one contact connection lug 18.1 of the at least one second contact region 18 of each busbar 14, 14A, 14B, 14C are each electrically contacted or connected by means of an integral bond 17, for example a weld seam connection, soldered connection or adhesive connection, to the corresponding external contact surfaces 2.1, 2.1A, 2.1B, 2.1C, 2.1D of the power module 2, 2A, 2B, 2C or to the at least one further external contact surface 2.2, 2.2A, 2.2B, for example one of the supply connections 32, 32A, 32B or the load connection 34.

As can be further seen from FIGS. 1 to 3, the shown exemplary embodiment of the power module arrangement 1 comprises three power modules 2, 2A, 2B, 2C. In the shown exemplary embodiment of the power module arrangement 1, the three power modules 2, 2A, 2B, 2C each comprise a first circuit carrier (not shown in detail), on which at least two semiconductor switches (not shown in detail) are arranged. Here, at least one first semiconductor switch, which is also referred to as a high-side switch, is electrically looped in between a first or second external contact surface 2.1A, 2.1B, which is connected to a first or positive external supply connection 32A, and a fourth external contact surface 2.1D, which is connected to the at least one external load connection 34. At least one second semiconductor switch, which is also referred to as a low-side switch, is electrically looped in between a third external contact surface 2.1C, which is connected to a second or negative external supply connection 32B, and the fourth external contact surface 2.1D, which is connected to the at least one external load connection 34. The control connections of the at least two semiconductor switches are each electrically connected to at least one external contact element 2.2 that is arranged on a second circuit carrier and can be contacted by at least one control line of an external control contact device. The second circuit carrier is connected to the first circuit carrier via a soldered connection or sintered connection or welded connection or adhesive connection.

As can be further seen from FIGS. 1 to 3, the individual power modules 2, 2A, 2B, 2C are each surrounded by an enclosure 3, which has a recess 5 in the region of the external contact surfaces 2.1, 2.1A, 2.1B, 2.1C, 2.1D, so that the external contact surfaces 2.1, 2.1A, 2.1B, 2.1C, 2.1D can be contacted. In the region of the external contact surfaces 2.1, an exposure 7 is made in the enclosure 3 so that the contact surfaces 2.1 are exposed and can be contacted.

As can be seen in particular from FIGS. 1 to 3, the individual power modules 2A, 2B, 2C each comprise a first and a second external contact surface 2.1A, 2.1B, which are connected to the first or positive external supply connection 32A via a first connection interface 10A, a third external contact surface 2.1C, which is connected to the second or negative external supply connection 32A via the first connection interface 10A, and two fourth contact surfaces 2.1D, which are each connected to an external load connection 34 via a second connection interface 10B. Thus, the three power modules 2A, 2B, 2C each have a first connection interface 10A, which electrically connects the corresponding power module 2A, 2B, 2C to the first or positive supply connection 32A and the second supply connection 32B, and a second connection interface 10B, which electrically connects the corresponding power module 2A, 2B, 2C to the corresponding load connection 34. Here, the two fourth external contact surfaces 2.1D of a first power module 2A arranged at the top in the illustration are electrically connected to a load connection 34 designed as a first phase connection 34U and provide a first phase current for an electric machine. The two fourth external contact surfaces 2.1D of a second power module 2B arranged centrally in the illustration are electrically connected to a load connection 34 designed as a second phase connection 34V and provide a second phase current for the electric machine. The two fourth external contact surfaces 2.1D of a third power module 2C arranged at the bottom in the illustration are electrically connected to a load connection 34 designed as a third phase connection 34W and provide a third phase current for the electric machine.

In the shown exemplary embodiment of the power module arrangement 1, a capacitor assembly 30, which comprises a plurality of film capacitors (not shown), provides the first or positive supply connections 32A and the second or negative supply connections 32B for the three power modules 2, 2A, 2B, 2C, which are supported by a support element 36 made of plastics material. The three phase connections 34U, 34V, 34W are each connected to a three-phase electric motor (not shown in detail). In addition, the three power modules 2, 2A, 2B, 2C are each thermally coupled to a cooling device 9 via a metal structure 4 arranged on the underside of the individual power modules 2, 2A, 2B, 2C in order to dissipate heat loss caused by the individual power modules 2, 2A, 2B, 2C.

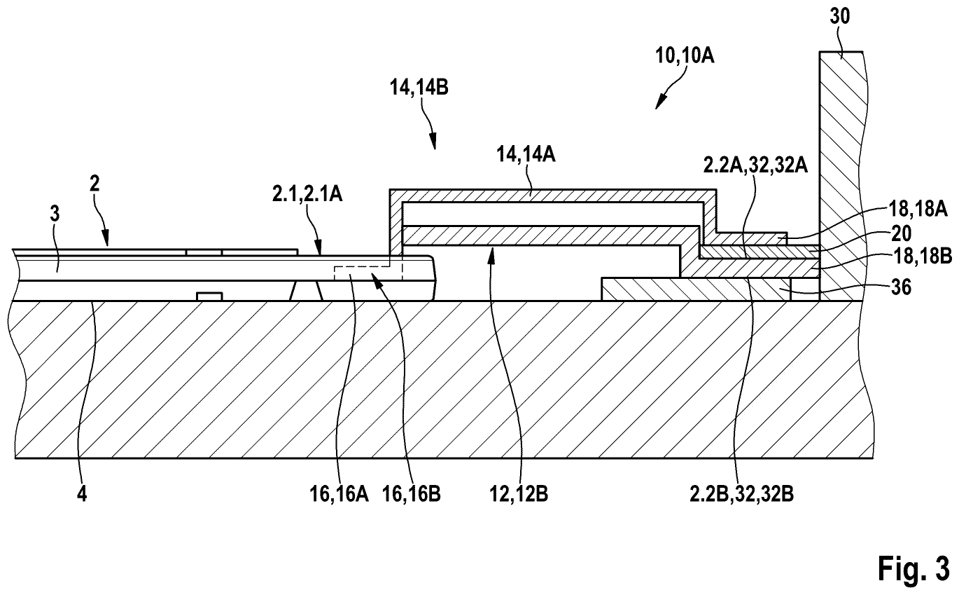

As can be further seen from FIGS. 3 and 4A or 4B, the first connection interface 10A of each of the power modules 2, 2A, 2B, 2C in the shown exemplary embodiment comprises a first external contact device 12A, which electrically connects the first and second external contact surface 2.1A, 2.1B of the corresponding power module 2, 2A, 2B, 2C to the first supply connection 32A and electrically connects the second external contact surface 2.1B of the corresponding power module 2, 2A, 2B, 2C to the second supply connection 32B. For this purpose, the first contact device 12A comprises at least two busbars 14A, 14B, each of which has at least a first contact region 16 and a second contact region 18.

The respective busbars 14A, 14B of the first contact device 12A are preferably each designed as punched and bent parts made of a sheet metal material, but can also be, for example, lasered bent sheet metal parts.

A power module 2 and the supply connections 32, 32A, 32B or load connections 34 assigned to it are spaced apart from one another within the power module arrangement 1 by a bridging distance T. The external contact surfaces 2.1, 2.2 to be electrically contacted via the busbars 14A, 14B are arranged at a distance from one another, for example in the X direction of a Cartesian coordinate system, such that they are each oriented in parallel with an orientation axis AA pointing in the direction of the Z axis. In the exemplary embodiment, the corresponding external contact surfaces 2.1, 2.2 are arranged in the same plane or at least in parallel planes to one another. In principle, the corresponding external contact surfaces 2.1, 2.2 could also be arranged in a certain plane position, rotating about the orientation axis AA over the angle β.

The first busbar 14A has at least one contact connection lug 16.1, 18.1 in each case on its first contact region 16 and its second contact region 18. The two contact connection lugs 16.1, 16.2 in the first contact region 16 of the first busbar 14A are each electrically connected to mutually spaced first and second external contact surfaces 2.1, 2.1A, 2.1B of a corresponding power module 2, 2A, 2B, 2C. In contrast, the second contact region 18 has only one contact connection lug 18.1, which electrically connects a first further external contact surface 2.2A. The electrical connection of the contact connection lugs 16.1, 16.2, 18.1 is made by an integral bond 17 with the correspondingly assigned external contact surface 2.1A, 2.1B, 2.2A. In the following, for example or preferably, a weld seam connection 17A is assumed as the integral bond 17, but the statements can alternatively also apply to a soldered or adhesive connection as the integral bond 17. In each case, a continuous welded connection 17A is formed within the first and second contact connection lugs 16.1, 16.2. In contrast, the welded connection 17A formed on the contact connection lug 18.1 in the second contact region 18 is interrupted multiple times by through-openings D formed in the contact connection lug 18.1. Through the through-openings D, multiple contact elements K are formed within the contact connection lug 18.1, which then in turn each have portions 17a of the weld seam connection 17A. In contrast to different contact connection lugs 16.1, 16.2, 18.1, contact elements K of a contact connection lug 18.1 are electrically contacted by an identical, contiguous, exposed external contact surface 2.2A. The weld seam connection 17 is formed between outer boundary edges 16.11, 16.12, 16.21, 16.22, 18.11, 18.12 of each contact connection lug 16.1, 16.2, 18.1 transversely, in particular at right angles, to the extension of the contact connection lugs 16.1, 16.2, 18.1 in the direction of the continuation of the busbar 14A. Furthermore, portions 17a of the weld seam connection 17A extend along a common axis on all formed contact elements K. One, two, three or more through-openings D can be provided, depending on the application. Each through-opening D is designed, for example, as a slot having a slot width b. Preferably, the through-opening D is in the form of an elongate hole. The through-openings D are open toward an end edge 18.13 of the contact connection lug 18.1. The elongate hole then extends from the end edge 18.13 in the direction of the first contact region 16, preferably oriented in the direction of the continuation of the busbar course, which adjoins the contact connection lug 18.1. Additionally or alternatively, the longitudinal axis of an elongate hole as the through-opening D extends in the direction of an axis of symmetry S of the electrically contacted external contact surface 2.1, 2.2 in question.

The second busbar 14B also comprises a first and a second contact region 16, 18. In contrast to the first busbar 14A, the second busbar 14B in this exemplary embodiment has only one contact connection lug 16.1, 18.1 per contact region 16, 18. In its second contact region 18.1, the contact connection lug 18.1 has, for example, two, three or more contact elements K, which are formed by corresponding through-openings D within the contact connection lug 18.1. The contact connection lug 16.1 in the first contact region 16 also has a through-opening D, therefore forming two contact elements K. Thus, in both contact regions 16, 18, portions 17a of a particular weld seam connection 17A are arranged on the corresponding contact elements K of the contact connection lug 16.1 or the contact connection lug 18.1. Furthermore, the through-opening D within the contact connection lug 16.1 in the first contact region 16 does not begin at its end edge 16.13, but at a distance e from it.

The contact connection lug 16.1 in the first contact region 16 is electrically connected to a third external contact surface 2.1C of the power module 2, 2A, 2B, 2C.

The two busbars 14A, 14B are arranged within a stack arrangement at a distance a from one another for electrical isolation. In addition, an insulating material, for example in the form of a spacer, for example as an injection-molded polymer component, is inserted between the two busbars 14A, 14B. Alternatively, an insulating protective film or something comparable can be provided, for example.

FIG. 4B shows, in a plan view of an electrically connected power module 2, 2A, 2B, 2C, in addition to the two above-described busbars 14A, 14B, also a third busbar 14C, which connects the power module 2, 2A, 2B, 2C to a load connection 34. The third busbar 14C has, in its first contact region 16, two contact connection lugs 16.1, 16.2, which are each electrically contacted by a fourth contact surface 2.1D of the power module 2, 2A, 2B, 2C, and has, in its second contact region 18, a contact connection lug 18.1, which is connected to the phase connection 34U, 34V, 34W of an electric motor. All contact connection lugs 16.1, 18.1 have through-openings D, which extend to the end edge 16.13, 18.13 of the associated contact connection lug 16.1, 18.1. All contact elements K formed by the through-openings D have corresponding portions 17a of a weld seam connection 17A.

In general, a portion 17a of the integral bond 17 or of the welded connection 17A formed on a contact element K extends substantially from an outer boundary edge of the correspondingly assigned contact connection lug 16.1, 16.2, 18.1 to an outer boundary edge of the next adjacent through-opening D (if these are the outermost contact elements K formed) or extend from each outer boundary edge of two through-openings D between which the corresponding contact element K is formed.

In principle, the number of contact connection lugs 16.1, 18.1 and the number of contact elements K formed per contact connection lug 16.1, 18.1 depend on the specific application in which the contact device 12 is to be used. The present invention is visualized with respect to the number of contact connection lugs 16.1, 18.1 and the number of contact elements K only by way of example, without being limited to the exemplary embodiments shown.

FIG. 4C shows very schematically the arrangement of a current detection device 40 in the region of a through-opening D of a contact connection lug 16.1 in a plan view. Only one end of a simplified busbar 14, 14C is shown, which is integrally connected, in particular by means of a weld seam connection, to an external contact surface 2.1D of a power module 2 via the contact connection lug 16.1 formed at the end of the busbar. The external contact surface 2.1D is, for example, a provided phase connection of an AC connection of the power module 2. The current detection device 40 can alternatively also be arranged in the region of a through-opening D of a contact connection lug 18.1 in the second contact region 18 of the busbar 14C (not shown). The current detection device 40 comprises at least one current sensor 40A, which at least partially dips into the through-opening D of the contact connection lug 16.1.

Furthermore, the current detection device 40 is designed to detect an alternating current within the busbar 14C without contact. Preferably, the current sensor 40A is designed as a magnetic sensor that detects a field strength of a magnetic field generated by the alternating current or phase current through the busbar 14C. The alternating current or phase current through the busbar 14C can be ascertained from the detected field strength of the magnetic field around the busbar 14C. To ascertain the alternating current or phase current through the busbar 14C, an evaluation and control unit (not shown) can preferably be used, which receives output signals from the at least one current sensor 40A. Based on the output signals received from the at least one current sensor 40A, the evaluation and control unit can calculate the alternating current or phase current through the busbar 14C. The at least one current sensor 40A can be designed, for example, as a Hall sensor, TMR sensor (TMR: tunnel magnetoresistance), GMR sensor (GMR: giant magnetoresistance) or AMR sensor (AMR: anisotropic magnetoresistance). In addition, other suitable sensor principles can also be used to measure the alternating current or phase current through the busbar 14C. The at least one current sensor 40A can in principle comprise two sensor elements, which are arranged mirror-symmetrically to a central transverse plane of the measuring portion of the busbar 14C and can form a sensor pair that can carry out a differential measurement of the alternating current or phase current through the busbar 14C. To hold and/or position the current sensor 40A on the power module 2, a holding and/or positioning device 40B can be arranged thereon. This can be, for example, an injection-molded part made of an insulating polymer material, which can be fastened to the power module 2, for example by means of a frictional fit and/or form fit. Alternatively, the holding and/or positioning device 40B is provided as an integral part of the enclosure 3 of the power module 2. The position of the current sensor 40A relative to the through-opening D or to the existing magnetic field around the busbar 14C is fixed in a defined manner by accommodating the current sensor within a receptacle 40b, for example within an opening which is complementary to the housing of the current sensor 40A. The flexible region of the busbar 14C present through the through-opening D is advantageously used as a measuring region for detecting an alternating current or phase current through the busbar 14C. In the same way, in an above-described power module arrangement 1, all alternating currents or phase currents at the corresponding phase outputs can be measured. Alternatively, a current detection device described in this way can also be arranged in the contact region 16, 18 of busbars 14A, 14B on the power supply side of the power module 2, for example in the region in which contact connection lugs 16.1, 16.2, 18.1 of busbars 14A, 14B are electrically connected to external contact surfaces 2.1A, 2.1B, 2.1C of the power module or further external contact surfaces 2.2A, 2.2B of a connected electrical functional assembly, for example the power supply connections 32A, 32B of a capacitor group 30.

1-12. (canceled)

13. A contact device for electrically contacting at least two electrical functional components of an electrical and/or electronic circuit and/or subcircuit within at least one connection interface, the contact device comprising:
at least one busbar which extends from at least a first to a second contact region and is configured such that, when a functional component is electrically contacted by different contact regions of the busbar, a current path can be formed within the busbar between the first and the second contact region, wherein the electrical contacting of at least one contact region with at least one external contact surface of one of the functional components is formed by an integral bond including a weld seam connection;
wherein each contact region of the first and second contact regions has at least one contact connection lug for integral connection to an external contact surface of one of the functional components, wherein the integral bond is formed between outer boundary edges of the at least one contact connection lug transversely to an extension of the contact connection lug in a direction of a continuation of the busbar and is interrupted by at least one through-opening in the contact connection lug, forming at least two contact elements which exclusively have portions of the formed integral bond.

14. The contact device according to claim 13, wherein the through-opening is an elongate hole, wherein a longitudinal axis of the elongate hole is oriented in a direction of an extension of the busbar and/or in a direction of an axis of symmetry of the electrically contacted external contact surface of the functional component.

15. The contact device according to claim 13, wherein portions of the integral bond on all contact elements are arranged along a common axis.

16. The contact device according to claim 15, wherein the portion of the integral bond formed on each of the contact elements extends substantially from an outer boundary edge of the contact connection lug to an outer boundary edge of the through-opening or extends from each outer boundary edge of two through-openings between which the contact element is formed.

17. The contact device according to claim 13, wherein at least one of the through-openings of the at least one contact connection lug extends to an end edge of the at least one contact connection lug, which also forms one edge of the busbar, and the at least one of the through-openings on a side facing away from the end edge of the at least one contact connection lug, in the direction of the extension of the busbar, projects beyond adjacent portions of the integral bond y a distance of from 1 to 30 mm.

18. The contact device according to claim 17, wherein at least one, of the at least one through-opening of the at least one contact connection lug extends to a distance of from 1 to 30 mm from the end edge of the at least one contact connection lug, which also forms one of the end edges of the busbar, and the at least one of the through-openings on the side facing away from the end edge of the at least one contact connection lug, in the direction of the extension of the busbar, extends to a distance of from 1 to 30 mm in front of another contact connection lug.

19. The contact device according to claim 13, wherein the contact device includes at least two busbars which are electrically isolated from one another and to which different electrical potentials of an associated functional component can be applied.

20. The contact device according to claim 13, wherein the at least one busbar is formed from a plate-like base material having a plate thickness between two opposite outer surfaces, from a sheet metal material made of copper or a copper alloy.

21. A power module arrangement, comprising:
at least one power module which includes a plurality of semiconductor switches and at least one external contact surface; and
at least one connection interface which includes at least one contact device including:
at least one busbar which extends from at least a first to a second contact region and is configured such that, when a functional component is electrically contacted by different contact regions of the busbar, a current path can be formed within the busbar between the first and the second contact region,
wherein the electrical contacting of at least one contact region with at least one external contact surface of one of the functional components is formed by an integral bond including a weld seam connection,
wherein each contact region of the first and second contact regions has at least one contact connection lug for integral connection to an external contact surface of one of the functional components, wherein the integral bond is formed between outer boundary edges of the at least one contact connection lug transversely to an extension of the contact connection lug in a direction of a continuation of the busbar and is interrupted by at least one through-opening in the contact connection lug, forming at least two contact elements which exclusively have portions of the formed integral bond;
wherein at least one contact connection lug of the at least one busbar is integrally connected by the weld seam connection, to the external contact surface of the power module.

22. The power module arrangement according to claim 21, wherein the connection interface includes a first contact device and is configured to electrically connect at least one first external contact surface of the at least one power module to a first supply connection by a first busbar and to electrically connect at least one second external contact surface of the at least one power module to a second supply connection by a second busbar.

23. The power module arrangement according to claim 21, wherein a second connection interface includes a further contact device and is configured to electrically connect at least one fourth external contact surface of the at least one power module to a load connection by a further busbar.

24. The power module arrangement according to claim 23, wherein the at least one power module includes three power modules, wherein the at least one fourth external contact surface of a first power module of the power modules is electrically connected to a load connection configured as a first phase connection and provides a first phase current for an electric machine, wherein the at least one fourth external contact surface of a second power module of the power modules is electrically connected to a load connection configured as a second phase connection and provides a second phase current for the electric machine, and wherein the at least one fourth external contact surface of a third power module of the modules is electrically connected to a load connection configured as a third phase connection and provides a third phase current for the electric machine.
